(19) United States
(12) Patent Application Publication
(10) Pub. No.: US 2025/0140717 A1
(43) Pub. Date: May 1, 2025

(54) STRIPLINE MONOLITHIC MICROWAVE INTEGRATED CIRCUIT (MMIC) INTERCONNECT ON RECESSED LOW TEMPERATURE CO-FIRED CERAMIC (LTCC)

(71) Applicant: BOARD OF TRUSTEES OF THE UNIVERSITY OF ARKANSAS, Little Rock, AR (US)

(72) Inventors: Samir El-Ghazaly, Fayetteville, AR (US); Latarence Butts, Fayetteville, AR (US); H. Alan Mantooth, Fayetteville, AR (US)

(73) Assignee: BOARD OF TRUSTEES OF THE UNIVERSITY OF ARKANSAS, Little Rock, AR (US)

(21) Appl. No.: 18/929,735

(22) Filed: Oct. 29, 2024

Related U.S. Application Data
(60) Provisional application No. 63/595,197, filed on Nov. 1, 2023.

(51) Int. Cl. H01L 23/66; H01P 5/107

(52) U.S. Cl. CPC H01L 23/66; H01P 5/107; H01L 2223/6633; H01L 2223/6655; H01L 2223/6683

(57) ABSTRACT

Disclosed herein is a stripline interconnect system for high-frequency signal transmission. The interconnect is positioned within a recessed area of a substrate, enabling a reduced height. Included in this design is a dielectric ramp, manufactured on the substrate, that facilitates a smooth transition from transmission dielectric to height of the wafer. Formed using aerosol jet printing, a center conductor extends from the substrate, traverses the dielectric ramp, and connects to wafer pads. To provide for electromagnetic confinement and reduce external interferences, a dielectric is printed over the center conductor, forming an arch, which is subsequently shielded with a printed metal covering. This design provides for reduced insertion and reflection losses, low dispersion, and increased signal isolation. This stripline interconnect is of particular interest for applications desiring precise high-frequency signal transmission between integrated circuit wafers and external circuitry.

### CROSS-REFERENCE TO RELATED APPLICATIONS

This application claims the benefit of U.S. Provisional Patent Application No. 63/595,197 filed on Nov. 1, 2023, and incorporates the provisional application by reference in its entirety into this document as if fully set out at this point.

### GOVERNMENT LICENSE RIGHTS

This invention was made with government support under grant number DE-NA0002839 awarded by the Department of Energy. The government has certain rights in the invention.

### BACKGROUND OF THE INVENTION

### 1. Field of the Invention

The subject matter disclosed herein relates to radio-frequency (RF) electronics and microwave engineering, with a particular aim at enhancing the performance of Monolithic Microwave Integrated Circuits (MMIC). To that end, the invention introduces a stripline interconnect designed explicitly for recessed Low-Temperature Co-fired Ceramic (LTCC) substrates, offering robust performance for W-band MMICs.

### 2. Description of the Related Art

The packaging of electronic systems has been of interest since the development of integrated circuits in the mid-20th century, particularly in the context of electronic systems used for transmission and reception of signals. The performance that is ultimately achieved by a millimeter wave system is largely reliant upon the methods used to integrate and connect its high-frequency components. For integrated circuits that transmit and receive high-frequency signals, the interconnect that joins the wafer to the circuit board or the package is highly susceptible to performance degradation through losses and signal distortion. This sensitivity results from the magnified radiative, coupling, ohmic, dielectric, and reflection losses that high-frequency components experience. While these losses are common to typical transmission structures on the circuit board, the disproportionate transition that typically occurs at the interconnect causes higher losses and distortion. The challenges posed by these losses have driven the evolution and development of packaging materials and methods over the years.

As frequency increases, especially in the millimeter wave spectrum (30 to 300 GHz), signals radiate more from a given structure into the surrounding environment. Additionally, the capacitive coupling between a given transmission structure and neighboring structures increases. Ohmic losses are heightened at high frequencies due to the skin effect. Transmission losses due to the conductivity of the dielectric medium (or IC substrate on which the circuit elements are fabricated) are also magnified at high frequencies. Impedance mismatch in millimeter wave systems often occurs between components like antennas, transmission lines, and the associated circuitry. This mismatch can result in signal reflections, which lead to losses. These reflective losses become significant at large electrical lengths, which increase with frequency for a given structure. In addition to the losses caused by the transmission of the signal along the interconnect, the performance of millimeter wave systems is also degraded due to high operating temperatures. As a result, the material of the substrate and the placement of the integrated circuit onto the substrate are crucial determinants of system performance.

Historically, FR4 materials, a common type of flame-resistant fiberglass-reinforced epoxy laminate, have been used for circuit board substrates and transmission dielectric since the late 1960s. However, low-temperature cofired ceramic (LTCC) which is a multilayer glass-ceramic substrate that can be fired (or sintered) at lower temperatures than typical ceramics, was introduced as an alternative in the late 1990s due to its advantageous electrical properties, notably its low dielectric loss tangent and high thermal conductivity. The term “dielectric loss tangent” represents how much signal energy is lost as heat when passing through a dielectric material. A lower value indicates better performance with fewer losses. The low dielectric loss tangent decreases the substrate losses for the transmission lines and allows the system to output higher power levels. The high thermal conductivity of the dielectric allows heat to be removed from the integrated circuit more quickly and lowers the operating temperature. This is important since higher temperatures increase ohmic losses and noise, which are both detrimental to high-frequency electronics. LTCC is also an attractive substrate because the processing methods allow components to be integrated into the substrate. This allows compact, high-density systems to be created, which also experience the aforementioned benefits. Furthermore, the hermeticity of the ceramic substrate extends its application to extreme environments, including space.

Indeed, low-temperature cofired ceramic has emerged as a promising substrate for high-frequency applications due to the low dielectric losses that it provides. The fabrication methods used for LTCC make this substrate even more suitable for multichip modules and 3D systems that integrate components into the board itself. Echoing the points above, its high thermal conductivity makes it an attractive substrate for high-power applications, or applications where operating temperature must be kept at a minimum. The hermeticity of the ceramic substrate extends its application to extreme environments including space. As a result, the development of millimeter wave systems in LTCC has received increased attention, with advancements like W-Band differential microstrip lines, and laminated waveguides for 110 GHz being developed. In line with these developments, several W-Band radar systems have been fabricated in this dielectric as well.

Turning now to interconnects, the microstrip line, a type of transmission line commonly used on printed circuit boards where a strip of metal is printed on one side of a dielectric substrate and a continuous ground plane on the other, was among the first interconnect methods developed for high-frequency signals. Although it was originally conceived in the 1950s, it was implemented following the maturity of printed circuit board technology in the 1970s. The stripline, another type of transmission line where the conductive strip is sandwiched between two ground planes in a dielectric substrate, was conceived in the same era as the microstrip line. The coplanar transmission line, which has a central conductor strip with ground planes on either side, all on the same plane, was invented in the late 1960s, and further improved the performance of the transmission line. The ground-backed coplanar waveguide introduces a ground plane beneath the coplanar structure, presenting an incremental improvement on this line by combining the microstrip and coplanar waveguide technologies. This remains state of the art for high-frequency transmission lines on circuit boards. Since the 1950s, wire bonds, which are thin metal wires used to connect components, have been employed to connect transmission lines on the circuit board to the metallization on the integrated circuit. Later on, ribbon bonds, which are wider flat metal strips as opposed to thin wires, were used for this purpose since their higher surface area experiences less loss due to the skin effect.

Aerosol jet printing (AJP) has also been investigated as a technology to fabricate improved high-frequency interconnects due to the high resolutions that it can achieve. This technique uses an aerosolized fluid containing nanoparticles to print fine-featured structures onto substrates. The fluid is dispensed through a nozzle, allowing for precise deposition onto desired locations. In addition to allowing rapid prototyping, aerosol jet printing allows the definition of complex and tapered interconnect structures that cannot be achieved with ribbon bonds. Additionally, AJP has been shown to improve isolation for transmission lines through the additive manufacturing of shielding structures, which also have the potential to be complex in shape. The use of aerosol jet printing in combination with LTCC was recently investigated with the printing of high-resolution interconnects for frequencies up to 210 GHz and has been proposed for the transmission of much higher frequencies due to the resolutions that can be achieved.

Given the challenges outlined above, as the demand for high-frequency electronics grows, especially in advanced applications like FMCW radar, understanding and mitigating losses, such as radiation and interference, remains of particular interest. Equally of interest is the integrity of the signal and the thermal performance of assembly methods, especially in high-power applications. Therefore, further development is needed.

### SUMMARY OF THE INVENTION

Disclosed herein is a low-loss assembly technique for W-band integrated circuits utilizing a recessed Low-Temperature Co-fired Ceramic (LTCC) stripline interconnect. The interconnect effectively shields against unwanted signal interference, combats radiative losses, and reduces signal dispersion, thereby significantly reducing insertion loss and the output reflection coefficient, while also achieving superior thermal performance.

Using aerosol jet printing to achieve fine resolutions, the stripline interconnect can be used in the sub-terahertz region and finds use as a high-performance interconnect for millimeter-wave integrated circuits, being particularly suited for applications that require high power and high signal integrity, such as FMCW radar, aerospace applications, and other extreme environments that require hermeticity.

### BRIEF DESCRIPTION OF THE DRAWINGS

FIG. 1 is a diagrammatical representation of a W-Band power amplifier MMIC, including its RF IN and RF OUT GSG pads which respectively receive and transmit a signal.

FIG. 2A is a cross-sectional diagram of the die assembly architectures disclosed herein, in particular showing surface placement with ribbon interconnects, with the substrate being FR4 or LTCC.

FIG. 2B is a cross-sectional diagram of the die assembly architectures disclosed herein, in particular showing surface placement with aerosol jet printed interconnects, with the substrate being FR4 or LTCC

FIG. 2C is a cross-sectional diagram of the die assembly architectures disclosed herein, in particular showing recessed placement with ribbon interconnects.

FIG. 2D is a cross-sectional diagram of the die assembly architectures disclosed herein, in particular showing recessed placement with aerosol jet-printed interconnects.

FIG. 3 is an isometric view of the structure used in the 3D electromagnetic and thermal modeling of the die assembly architecture disclosed herein.

FIG. 4A is an isometric view of the ribbon bonds that connect the GCPW to the die for surface placement assembly, such as may be used in the die assembly architecture of FIGS. 2A-2B.

FIG. 4B is an enlarged dimetric view of the ribbon bonds that connect the GCPW to the die for surface placement assembly, such as may be used in the die assembly architecture of FIGS. 2A-2B.

FIG. 5A is an enlarged dimetric view of an AJP interconnect as used on the surface placement embodiment of FIGS. 2A-2B.

FIG. 5B is an enlarged dimetric view of the ribbon bonds interconnecting the GCPW to the die as used on the surface placement embodiment of FIGS. 2A-2B.

FIG. 6 is an isometric view of the shielded AJP interconnect that connects the GCPW to the die for surface placement assembly used in the embodiments of FIGS. 2A-2B.

FIG. 7A is an isometric orthographic view of a stripline interconnect disclosed herein, shown from top to bottom.

FIG. 7B is a front orthographic view of a stripline interconnect disclosed herein, shown from top to bottom.

FIG. 7C is a side orthographic view of a stripline interconnect disclosed herein, shown from top to bottom.

FIG. 8 shows the power amplifier MMIC on a FR4 top layer metallization with DC wire bonds and RF ribbon bonds.

FIG. 9 shows the LTCC cavity as defined for the recessed MMIC placement.

FIG. 10 is a graph of transmission scattering parameters for the FR4 AJP, FR4ribbon, 9K7 AJP, 9K7 ribbon, 9K7 AJP recessed, 9K7 ribbon recessed, shielded recessed; port 2 represents the pads on the MMIC.

FIG. 11 is a graph showing S11 reflection scattering parameters for the FR4 AJP, FR4 Ribbon, 9K7 AJP, 9K7 ribbon, 9K7 AJP recessed, 9K7 ribbon recessed, shielded recessed; port 2 represents the pads on the MMIC.

FIG. 12 is a graph showing S22 reflection scattering parameters for the FR4 AJP, FR4 Ribbon, 9K7 AJP, 9K7 ribbon, 9K7 AJP recessed, 9K7 ribbon recessed, shielded recessed; port 2 represents the pads on the MMIC.

FIG. 13 is a graph showing the average values of S21, S11, and S22 scattering parameters between 77 and 81 GHz for several MMIC assembly topologies.

FIG. 14 is a graph showing the variance of S21, S11, and S22 scattering parameters between 77 and 81 GHz for several MMIC assembly topologies.

### DETAILED DESCRIPTION OF THE INVENTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

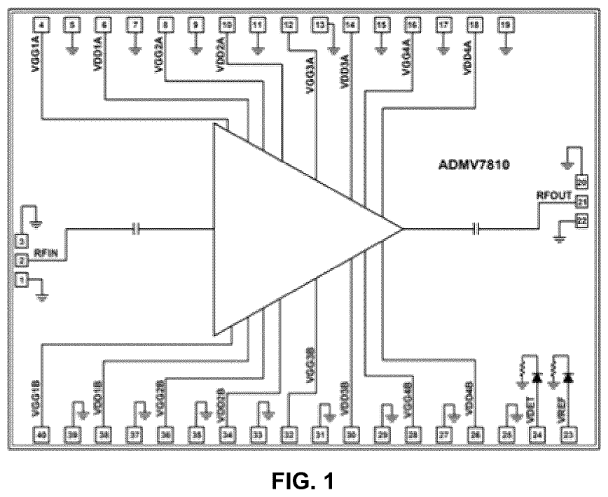

Shown in FIG. 1 is a power amplifier MMIC, a W-band component whose integration is of particular concern for system performance in systems such as radar and communications systems. For example, the power amplifier may be integrated into the transmit chain of W-band radar systems and used to achieve high transmit power. The power amplifier has an operational frequency of 81-86 GHz, a form factor of 2.999 mm×3.799 mm×0.05 mm, and RF bond pads that are 90 μm² with 40 μm between them. The input and output ports of the power amplifier have an impedance of 50 ohms, and grounded coplanar waveguide (GCPW) transmission lines with 50-ohm impedance are used to bring the W-band signal to and from the die. These GCPW transmission lines are a type of planar transmission line that is well-suited for W-band applications, having low losses and good isolation, which is helpful for maintaining the performance of the W-band signal.

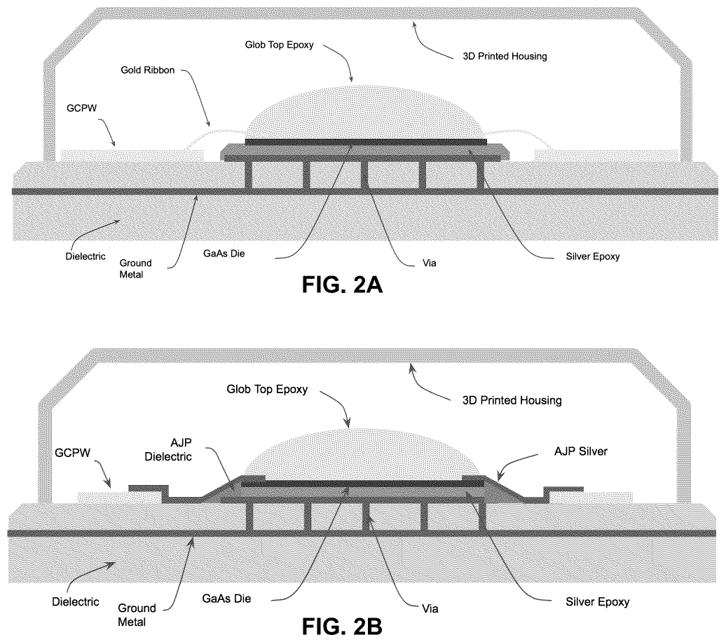

Disclosed herein are two different assembly methods for W-band MMICs (such as the power amplifier of FIG. 1) in LTCC packages: top layer placement and ground plane placement. Top layer placement is shown in FIGS. 2A-2B, and is advantageous because it reduces fabrication complexity. Ground placement is shown in FIGS. 2C-2D and is made possible using LTCC fabrication techniques. Such ground placement is advantageous because it may result in improvements to the thermal performance due to the large conductive area of the ground metallization, which may remove heat from the bottom of the chip at a faster rate, and due to the high thermal conductivity of LTCC. The top of the illustrated die is 0.06 mm above the GCPW in the surface placement cases of FIGS. 2A-2B, and is 0.06 mm below the GCPW in the recessed placement cases of FIGS. 2C-2D.

The distance between the MMIC and the GCPW transmission line determines the distance of the interconnect. Since a longer interconnect may experience more resistive losses, inductive losses, and parasitic effects, this distance may be minimized. However, small tolerances for this spacing increase fabrication costs and reduce yield. In the illustrated embodiments, a 5 mil separation is used. If LTCC is used as the substrate, its height may be 5 mil, while if FR4 is used as a substrate, its height may be 4 mil.

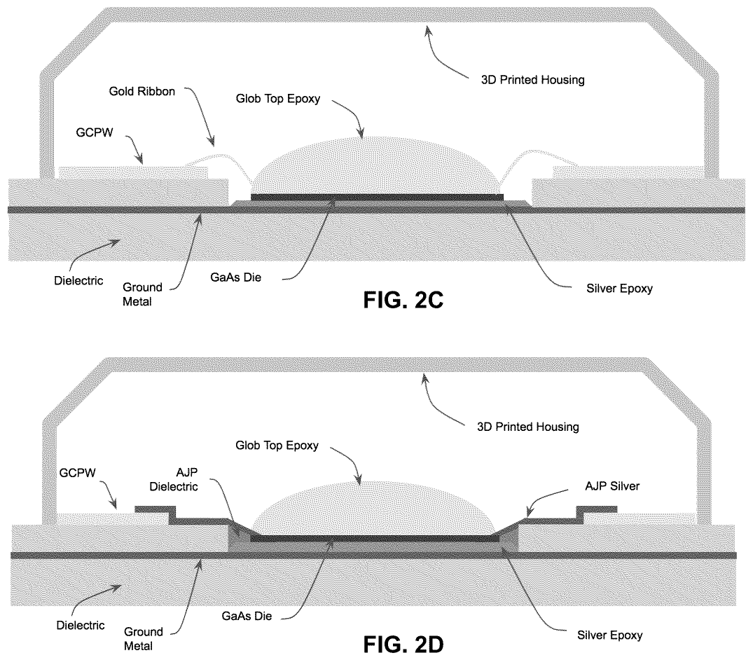

Also shown in FIGS. 2A-2D is the approach used to encapsulate and house the die. An ultraviolet-cured glob top epoxy covers the bare die and protects it against environmental contaminants. A 3D-printed housing covers the die for protection against mechanical damage. An isometric view of this assembly is shown in FIG. 3.

An isometric view of the assembly architecture is shown in FIG. 3. Electromagnetic simulations of the complete architect are used to calculate the expected performance of each method.

Although the interconnect between the GCPW and the die is less than 6 mil, the transmission of high-frequency signals over this length is still of particular concern. As frequencies increase, the interconnect and its properties have a large impact since losses are magnified. For a millimeter wave power amplifier MMIC, such as that described above, advanced transmission methods are to be utilized.

The design of conventional high-frequency interconnects entails consideration for dielectric loss, ohmic loss, radiative losses, interference losses, and reflective losses from an impedance mismatch. Therefore, the performance of prior art interconnects are not only impacted by the dielectric chosen but the interconnect method as well.

The advantages and challenges of knowing LTCC interconnects regarding transmission are now described. The advantages of such LTCCs include a low-loss tangent and the possibility for 3D architectures. The challenges include fabrication challenges that may be unique to the system, and the transmission accompanying the high dielectric constant of LTCC systems. As the dielectric constant of the 9K7 dielectric used in the LTCC is twice that of the Rogers 4350 dielectric used in FR4, the effective wavelength of the 9K7 signal will be roughly 0.7 that of the FR4 signal. Therefore, the electrical length of LTCC systems will be increased if transmission lengths remain similar, and impedance mismatch losses may therefore increase. Additionally, LTCC transmission lines have been shown to experience surface wave phenomena and decreases in bandwidth.

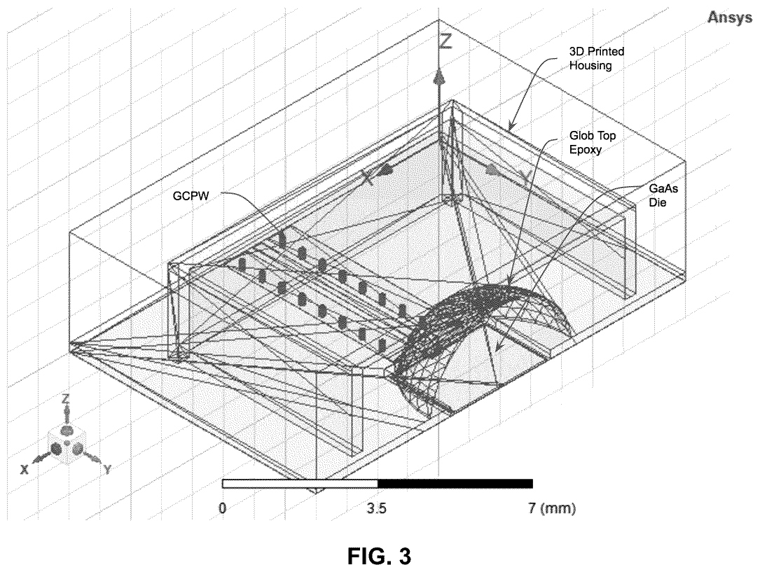

Due to these drawbacks of LTCC interconnects, the assembly configurations described herein utilize ribbon-bonded or AJP interconnects. Ribbon-bonded interconnects use ultrasonic bonding to attach a metallic ribbon to two metallic locations. For high-frequency applications, ribbons are advantageous as compared to wire bonds of the same cross-section due to the skin effect. Shown in FIG. 4A is an isometric view of the entire interconnect topology when ribbons are used, and shown in FIG. 4B is a zoomed-in dimetric view of the ribbon bond interconnect. Both FIG. 4A and 4B correspond to the assembly of FIG. 2A, in which the die rests on the top metallization, and is elevated above the GCPW. For GSG RF pads like those used in the illustrated example, one ribbon joins each pad to the terminals on the coplanar transmission line. The specific illustrated ribbons are gold ribbons with 0.5×3 mil cross-sections.

Ribbon bonds, when accomplished manually, may have significant variances in profile. At high frequencies, the ribbon length may be 40% of the wavelength. Additionally, the location of the ribbon bond may vary—the start of the ribbon dictates where the interconnect propagation begins.

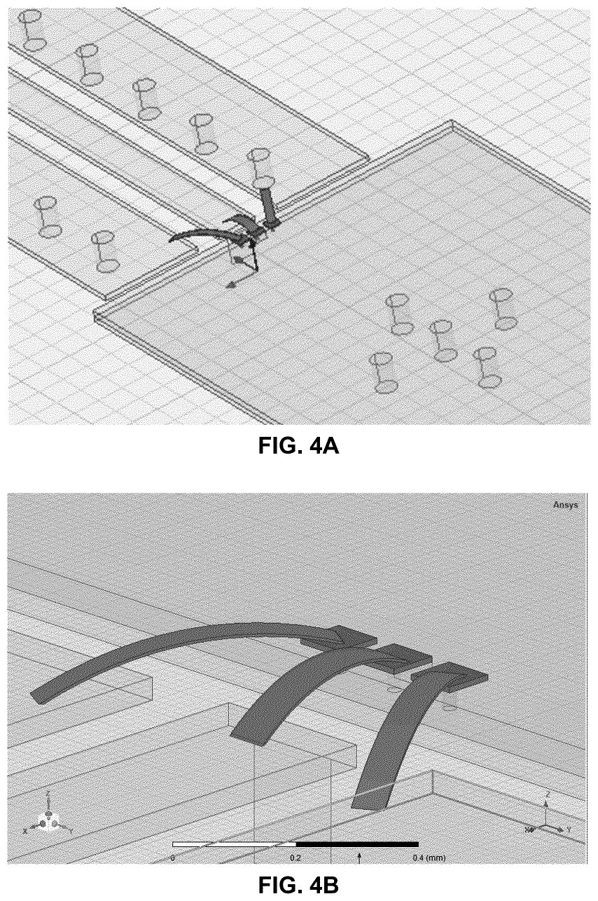

AJP is of particular value for millimeter wave systems due to the diverse materials that can be deposited, the complex architectures that can be constructed, and the fine resolutions that can be achieved. With AJP, metallic and dielectric materials can be deposited. In order to print a metal interconnect, a dielectric ramp is first printed for the metal to rest upon. FIGS. 5A and 5B illustrate the AJP interconnect on the surface and recessed placements of FIGS. 2B and 2D, respectively. During the printing of the metal interconnect, the AJP allows the definition of featured structures that may not be easily achieved using ribbons, without the concern of tensile strength. In the illustrated example, the AJP interconnects are tapered to gradually change from the width of the coplanar transmission line to the width of the GSG RF pads. This allows for a more gradual impedance transition. Unlike ribbon-bonded interconnects, the performance of AJP interconnects is not sensitive to a bond location because the wave remains confined until the end of the GCPW. For the AJP, the interconnect propagation will begin where the GPCW ends. Prior to this, AJP metal will contribute only to the added thickness of the coplanar grounds on the GCPW.

When the dimensions of transmission structures are proportional to the effective wavelength of the signal, the LTCC system may pose challenges because the high dielectric constant of LTCC causes its effective wavelength to decrease. Therefore, the use of aerosol jet printing in combination with LTCC has been investigated with regard to printing of high-resolution interconnects for frequencies up to 210 GHz, and has been proposed for the transmission of much higher frequencies due to the resolutions that can be achieved.

In an active environment (such as in the device described herein) where there are other sources of radiation or areas of susceptibility, circuit components or transmission lines are to be shielded. In cases such as these, rigid housings may be added to the transmission line to prevent inward radiation. AJP may be used for manufacturing the shields.

The dispersion and the linearity of the signal transmitted over the interconnect is to be considered in addition to crosstalk and interference. As explained, the power amplifier utilized herein is integrated with the transmit chain of an FMCW radar. A system of this sort relies on the outward transmission of a purely chirped signal with a high sweep rate. In this context, a purely chirped signal implies a linear frequency sweep containing low-phase noise, and a level frequency response or transmission profile. Significant dispersion along the interconnect would cause energy propagating along the transmission line to become significantly different for frequencies within the band, manifesting as a disturbance in the linearity of the frequency sweep, or similarly, the introduction of phase noise.

The stripline MMIC interconnect on recessed LTCC invention, detailed herein, is specifically designed for a recessed placement, incorporating a metal shield atop the printed metal interconnect. This interconnect is designed to transfer high-frequency signals between an integrated circuit wafer and external circuitry. A recessed placement proves helpful in reducing the overall height of the interconnect, a feature that becomes of particular interest for W-band applications, and also helps improve the continuity of the transmission and the thermal performance of the assembly.

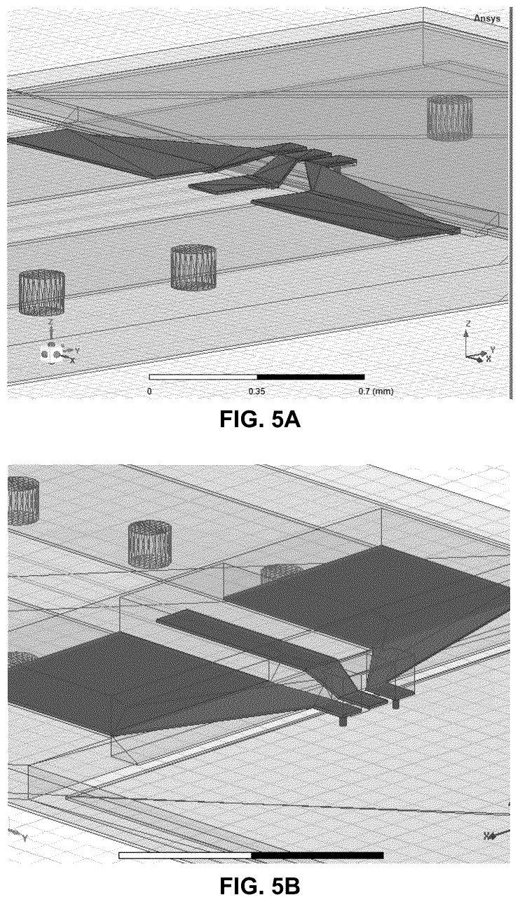

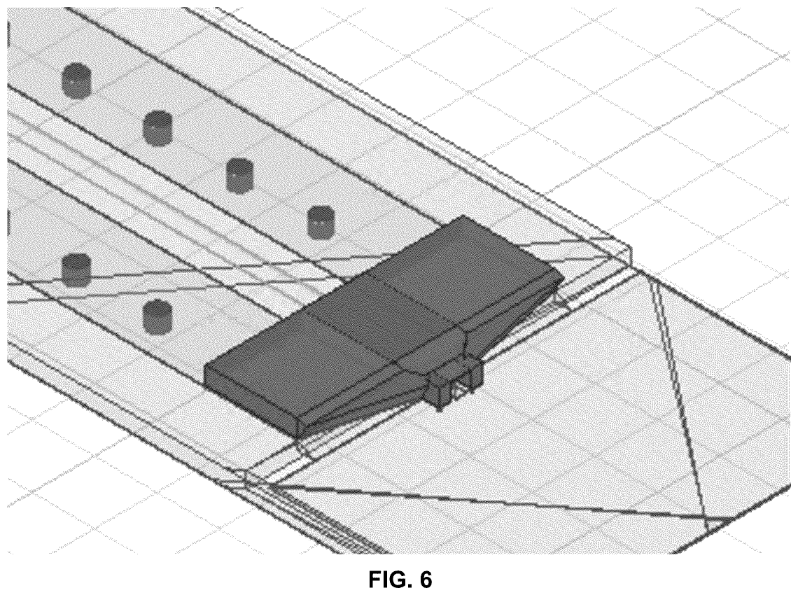

Generally speaking, a stripline is a type of transmission line used for high-frequency signals, sandwiched between two parallel ground planes. This structure helps ensure that the electromagnetic waves are strictly confined. The stripline transmission line is selected to improve the signal confinement at high frequencies and maintain a consistent relative permittivity as frequency increases. Shown in FIG. 6 is an isometric view of the stripline interconnect discussed, while FIGS. 7A-7C show an orthographic depiction.

The shield aids in confining the electric field to the dielectric layer, reducing radiation, while protecting the signal from external electromagnetic interferences. Similar to the shape of the printed interconnect, this shield is also tapered, improving the impedance-matching performance.

Production is as follows. Aerosol jet printing creates the stripline interconnect by printing the dielectric ramp, metal interconnect, dielectric medium, and metal shielding. The stripline interconnect connects a high-frequency wafer to an external transmission structure. In the recessed assembly, the wafer is placed onto the ground plane so that the top of the wafer is below the height of the transmission structure. First, a dielectric ramp is additively manufactured, which gradually transitions in height from the transmission dielectric to that of the wafer. Next, metallization, which connects the transmission structure to the wafer pads, is printed on top of the dielectric ramp. This forms a coplanar interconnect. The width of the printed metal gradually decreases from the width of the transmission line to the width of the pads on the wafer. Afterward, a dielectric is printed on top of the center conductor and the sides of the center conductor, forming an arch above the center conductor; this dielectric mirrors the thickness observed in the GCPW, providing for a uniform distance between the stripline and the shield and between the signal and the underlying ground plane. Finally, a metal shield is printed on top of the dielectric and connects the printed coplanar ground conductors. The printed dielectric and the printed metal follow the ramp and taper of the printed coplanar waveguide. This ensures the interconnect benefits from low insertion and reflection losses, low dispersion, and high isolation.

The stripline interconnect presents multiple advantages for high-frequency interconnects, from mitigating radiative losses and enhancing shielding to controlling dispersion, providing for suitability in advanced applications. Compared to traditional ribbon-bonded and grounded coplanar interconnects, the stripline increases the confinement of the signal.

In a ribbon-bonded interconnect, the distribution of the electric field between the ribbon and the ground plane changes significantly since the ribbon is arched. Additionally, the dielectric medium changes because the ribbon is projected into the air. This discontinuity of the field distribution and the dielectric causes an impedance mismatch which results in reflective losses. The ground coplanar transmission line improves the continuity of the field distribution between the transmission line and the interconnect since there is no arch in the metal. Furthermore, there is no air introduced to the dielectric medium since the metal rests on top of the dielectric.

The introduction of an additional ground plane amplifies the confinement of the electric field, reducing radiative losses. Additionally, this ground plane shields against electromagnetic interference from external sources. This shielding is useful, particularly when multiple devices are positioned closely with respect to one another. The dispersion discussed above is induced by variations in the effective dielectric constant with respect to frequency. Such variations are attributed in part to field distribution, which remains predominantly confined to the dielectric at lower frequency bands but tends to radiate more freely into the surrounding air as frequency escalates. This fluctuation in effective dielectric constant is pronounced in LTCC, given the disparity between the dielectric constants of air and LTCC.

Within the architecture of a stripline as described herein, field distribution alterations are subdued due to the encompassing confinement offered by the surrounding ground plane. Moreover, since the dielectric constant enveloping the signal line remains consistent, changes in the effective dielectric constant are moderated. Thus, even as the field distribution shifts with frequency variations, these shifts are not only subdued due to increased confinement but also occur within a more consistent dielectric backdrop. The stripline interconnect improves the grounded coplanar interconnect by adding a dielectric on top of the center conductor, and a metal shield on top of the dielectric. In the ribbon bonded and coplanar methods, part of the field distribution exists in the air due to fringing, contributing to radiation. In the stripline interconnect, the signal line is surrounded by the dielectric medium on all sides.

By confining the field distribution to a single medium, the radiative and reflective losses are minimized. The addition of a top conductor also reduces the radiative losses and improves the isolation compared to the coplanar line. With the addition of the top metal, the distribution of the electric field exists between the center conductor and the ground plane on all sides, preventing the signal from radiating into the environment. Reducing the radiative and reflective losses provided by the stripline interconnect is helpful for circuits operating at high frequencies.

The interconnect provides additional benefits for more advanced applications where complex signals are transmitted. In applications such as SFCW and FMCW radar, the frequency of the transmitted signal changes with time. For accuracy, these systems require that the temporal relationship between the frequencies in the generated signal remains consistent. Therefore, in addition to minimizing the losses at high frequencies, these systems also require consistency between frequencies. The stripline interconnect improves this consistency compared to conventional methods by reducing the frequency dependence of the propagation. In a coplanar interconnect, the distribution of the electric field increases significantly with frequency since it is unbounded. In the stripline interconnect, however, the field is bounded on all sides, and it changes less with frequency. This causes the losses to change less with frequency, maintaining the relative amplitudes of the frequencies in the transmitted signal. Furthermore, the consistency of the field distribution maintains the velocity of the signal as frequency increases.

Therefore, the stripline interconnect reduces the dispersion of transmitted signals which manifests as lower phase noise for systems such as continuous waveform radars. Coplanar propagation refers to a design where the signal and its associated ground elements are on the same plane, aiding in maintaining signal quality. The shield in the stripline arrangements further promotes this coplanar mode by providing for continuous connection between adjacent grounds, particularly during transitions in the interconnect.

The placement of the wafer on the ground plane improves the continuity of the electric field distribution, and it improves the thermal performance of the assembly. When the die is placed on the top of the transmission medium, the profile of the interconnect changes abruptly. This is because the ground plane for the die is at the same height as the top metallization for the transmission structure. The height transition required by the ground plane is significant. In the recessed topology disclosed herein, the ground plane is unchanged between the transmission line and the die. While the height of the ground plane is unchanged for the recessed topology, the height change required by the center conductor remains comparable for both placement methods.

The direct contact of the wafer with the ground plane also improves thermal performance. This thermal performance is helpful for advanced applications such as radar, where high power is required for large detection ranges. When the wafer is placed on the surface, vias are used to conduct heat from the bottom of the die to the ground plane below. However, the capacity of the vias to conduct heat is limited by their surface area. Conversely, the large surface area of the ground plane allows heat to be removed more quickly. Therefore, the recessed placement described herein allows the wafer to operate at lower temperatures for a given power level. This recessed placement is also easier to accomplish in LTCC due to the fabrication methods used.

In addition to permitting recessed topologies, LTCC offers additional benefits for both the electric performance of the interconnect and the thermal performance of the assembly. The low-loss tangent of the LTCC reduces the dielectric losses of the interconnect. This is important since the dielectric loss tangent increases with frequency and causes significant losses at high frequencies. The high thermal conductivity of the LTCC allows heat to be removed from the die more quickly. This lowers the operating temperature of the die, allowing for more efficient operation for the same power level. Also, using LTCC permits the development of hermetic modules necessary for space applications or environments where contaminants are prevalent.

Ultimately, the stripline interconnect on the recessed LTCC invention is a part of a wafer assembly. In the assembly, the wafer can be encased into a ceramic package, or it can be placed onto a ceramic board directly. Therefore, the invention can be carried around like any other chip component or circuit board. When completely encased in the ceramic, the chip will benefit from the hermiticity of the ceramic. This allows the chip to be resistant to liquids and other contaminants.

Continuing with the discussion of improvements, the stripline interconnect on recessed LTCC experiences the combined advantages of its methods and components. These constituents combine to create low loss, low distortion, and high-resolution interconnect with high thermal performance. This invention is suitable for advanced circuits that contain high-frequency components that operate at high power levels.

As explained, the stripline interconnect presents an improvement over the ribbon bond, which is typically used to connect integrated circuits to external transmission structures. This mitigates radiative losses at high frequencies by enhancing the confinement of the electromagnetic field on each side of the transmission line. The stripline interconnect also shields the transmission from external signals, reducing distortion from noise and crosstalk. Therefore, the stripline MMIC interconnect is advantageous in noisy environments where there are sources of radiation or several high-frequency circuits in close proximity. Furthermore, it decreases the change in transmission performance with frequency since the distribution changes less with increasing frequencies. This manifests as improved linearity and reduced dispersion. Ultimately, the reduction in dispersion reduces the phase noise introduced by the transmission structure. The mitigation of this distortion retains signal integrity central to the performance of high-frequency signals such as FMCW radar.

The method used to attach the integrated circuit to the circuit board is utilized after the fabrication of the board and after the attachment of the integrated circuit. The first benefit of aerosol jet printing is that it allows interconnects to be additively fabricated after the attachment of the integrated circuit. Aerosol jet printing also is a valuable technology for millimeter wave systems due to the diverse materials that can be deposited. With aerosol jet printing, metallic and dielectric materials can be deposited in multiple layers to create complex structures. During the printing of the metal interconnect, the AJP allows the definition of featured structures that cannot be achieved using ribbons. For example, the tapering of interconnects can be accomplished, which is not possible using ribbon interconnects. The tapering of the stripline interconnect gradually changes the width of the coplanar transmission line to the width of the GSG RF pads on the integrated circuit. This allows a more gradual impedance transition and reduces reflective losses due to impedance mismatch. The complex shapes that LTCC permits are also necessary for the shielding of complex transmission lines, which cannot be accomplished with the rigid, prefabricated shields that are typically used.

The fine resolutions that can be achieved by AJP are quite useful in high-frequency systems. Since the dimension of electronic structures is proportional to their wavelength, very small structures are required for higher frequencies. This is increasingly important in dielectrics with a high permittivity, such as LTCC. Unlike ribbon-bonded interconnects, the performance of AJP interconnects is not sensitive to a bond location. This is because the wave remains confined until the end of the transmission structure on the circuit board. For the AJP, the interconnect propagation will begin where the transmission line on the circuit ends. Prior to this, AJP metal will only contribute to the added thickness of the transmission lines on the circuit board.

Low-temperature cofired ceramics are advantageous for high-frequency interconnects because of their low-loss tangent and 3D architectures. The fabrication methods used for LTCC make this substrate even more suitable for multichip modules and 3D systems that integrate components into the board itself. Additionally, its high thermal conductivity makes it an attractive substrate for high-power applications, or applications where operating temperature is to be kept at a minimum. The hermeticity of the ceramic substrate extends its application to extreme environments including space. As a result, the development of millimeter wave systems in LTCC is of particular interest.

The recessed LTCC assembly used in this invention provides two main advantages, explained above. The first is the improved thermal performance achieved by placing the die directly on the ground plane. This allows the heat to be conducted through the large surface area of the ground metallization, as explained. Conversely, when placed on the surface of the circuit board, the heat produced by the wafer must first be conducted through vias that connect from the surface of the circuit board to the ground plane beneath. Due to the limited surface area of the vias, the heat cannot be conducted away from the die as quickly, and the operating temperature of the die increases. Secondly, as explained above, the recessed topology also improves the electrical performance of the interconnect because the impedance of the interconnect remains more consistent when the thickness of the substrate is reduced along with the width of the signal line on the stripline interconnect.

The use of AJP processes, the stripline interconnect, and the recessed LTCC substrate makes this invention particularly suitable for advanced high-frequency applications. Using the method, integrated circuits operating at high frequencies and high powers can be added to the system while experiencing menial loss and causing minimal dispersion.

Building on the understanding of the stripline interconnects, two construction methodologies, namely the ribbon-bonded FR4 method and the recessed LTCC topologies, have been tested. In both methods, the die attachment technique remains consistent: a silver conductive epoxy is employed to secure the back metalized die to the board metallization. This specific epoxy die attach method was chosen due to its efficiency and ease of implementation.

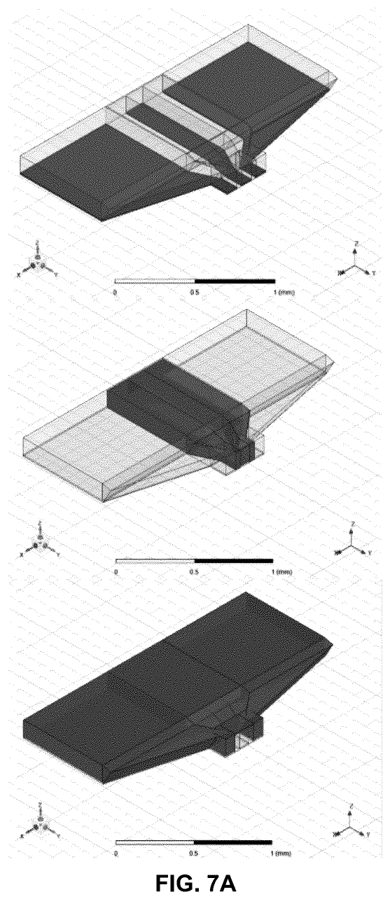

FIG. 8 provides a visual insight into the assembly of the FR4 ribbon bonded method before the final steps, where the glob top encapsulant and the printed housing are added. In this assembly, while wire bonds take on the role of forming the DC connections, the RF connections are entrusted to ribbon bonds.

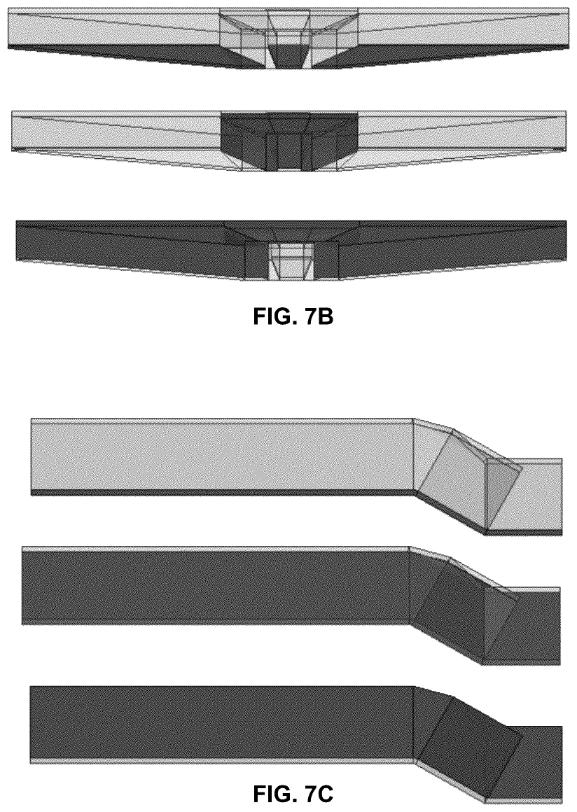

Moving on to the LTCC fabrication, standard procedures are employed. Initial stages included via holes being punched, which are then filled manually with conductive ink. Following this, the metallization process was carried out using screen printing. The layers of the structure were laminated and subjected to a vacuum before being sliced and fired. A feature of the top LTCC layer is a cutout that functions as a cavity for the die. This cutout, as shown in FIG. 9, is formed using a via-punching technique. Due to this method, the edges of the cavity tend to be somewhat irregular. For clarity, the central region of metallization depicted is positioned on the 2nd layer, while all other metallization rests on the top layer. Note that the metallization on the backside of the die is intimately bonded to this central region.

To offer some technical insights, the FR4 dielectric has a relative dielectric constant of 3.48, a dissipation factor of 0.0037, and a thermal conductivity measure of 0.71 W/m/K. In comparison, the 9K7 LTCC dielectric boasts a relative dielectric constant of 7.1, a loss tangent standing at 0.001, and a thermal conductivity of 4.6 W/mK. A point to note about the LTCC dielectric is its dimensional changes during firing, experiencing an X-Y shrinkage of 9.1% and a Z-axis shrinkage of 11.8%.

As verification, electromagnetic simulations were conducted using three-dimensional models of each assembly method in FIG. 2 to estimate performance. The transmission and reflection scattering parameters are used to characterize the interconnect as a two-port network. The first port represents the GCPW input, and the second port represents the RF pads on the power amplifier MMIC. Since the W-Band signal must also be delivered from the amplifier, the delivery from RF pads to the GCPW is important as well. Therefore, the reflection at each port is significant.

The finite conductivities of the metals are included in the study, and therefore the metal losses are considered. However, the metallization used between the FR4 and LTCC substrates was unchanged, and the geometries are largely identical. Therefore, although GCPW metal losses are considered, they do not contribute to the CPW differences between the results in FR4 and LTCC systems. The ohmic losses of the gold ribbon and silver aerosol jet-printed interconnects are included as well. Their ohmic losses may contribute to differences between the results, but not substantially.

The dielectric loss tangent is neglected. It is known that the loss tangent for LTCC can be substantially lower than that of FR4, leading to lower attenuation. In the FR4 and LTCC systems used here, the LTCC loss tangent is 4 times lower. However, this factor is disregarded from the analysis so that the effect of the dielectric, placement, and interconnect methods can be evaluated separately. Therefore, the lower loss tangent of LTCC remains a benefit in addition to the performance enhancement presented here. Additionally, 5.5 μm of GCPW transmission line is included in the simulation. The FR4 and LTCC GCPW transmission lines have attenuations near 0.07 dB/mm.

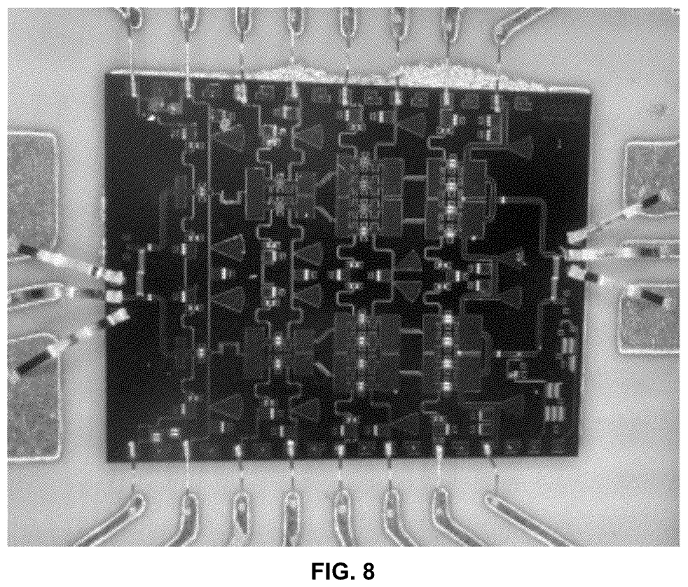

FIG. 10 presents the transmission characteristics for each assembly method. For the FR4, insertion loss of the ribbon bond and the printed interconnect appear comparable in magnitude. Both interconnects have a minimum loss value near 5 dB, but the ribbon bond has a slightly lower loss overall. The loss drops to 10 dB in the ribbon and FR4 interconnects around 79 GHz and 77.5 GHz, respectively. The printed interconnect experiences lower minimum loss and higher maximum loss for surface placement in LTCC.

For the surface placement in the LTCC, this type of similarity between the ribbon bond and the printed interconnect persists. The minimum loss value for both interconnects is near 2.5 dB. This is a meaningful improvement compared to the FR4. However, the loss for the ribbon bond and printed interconnect drops near 20 dB at 77.5 GHz and 79.8 GHz, respectively. In this case, the loss for the printed interconnects shifts to higher frequencies. Similarly to the FR4, the printed interconnect experiences lower minimum loss and higher maximum loss for surface placement in LTCC. Overall, the minimum loss is reduced, but the maximum loss is increased for the ribbon and printed interconnects when transitioning from the FR4 to the LTCC substrate.

The first observation from the responses in the recessed LTCC is the loss reduction. While the loss in the printed interconnect is a visibility lower, minimum losses near 2 dB are obtained for the printed and ribbon interconnects. Unlike the cases in the surface placement, the values for the loss are held constant throughout the band. The spurious increases insertion loss that was present in the previous methods is no longer present. This is also true for the surface LTCC assemblies. The recessed placements reduce both the loss and the variance of the loss.

Lastly, the stripline interconnect on the recessed die improves the performance further. The minimum loss is less than 1 dB. Additionally, the reduction in loss variation that the previous recessed placements showed is maintained.

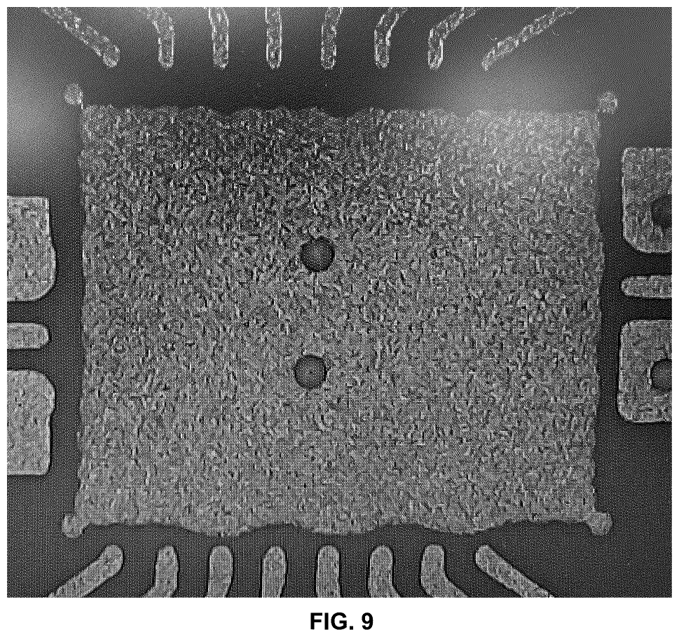

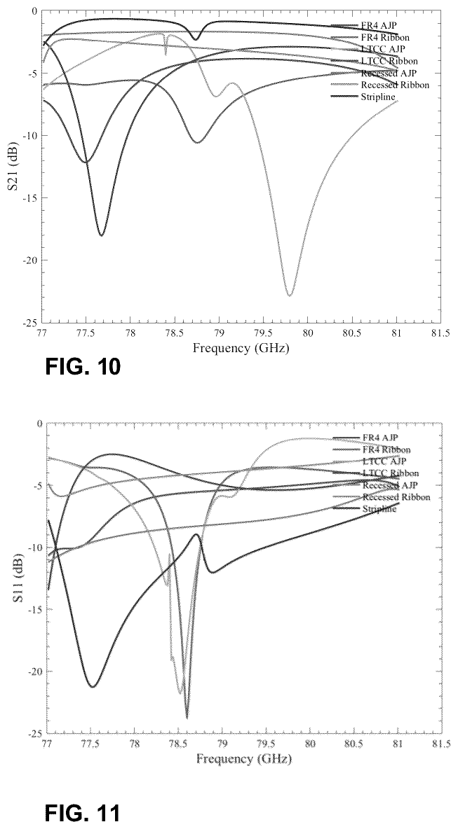

FIGS. 11 and 12 present the reflection scattering parameters for each assembly method. Port 2 represents the RF pads on the MMIC, while port 1 represents the input to the GCPW. For the FR4, the input reflection for the printed interconnect gradually increases from −10 dB to −5 dB. For the ribbon interconnect, the maximum input reflection is near −4 dB, and a spurious decrease in reflection toward −25 dB occurs at 78.5 GHz. The ribbon shows a larger maximum input return loss and a smaller minimum input return loss

For the surface placement in LTCC, the printed interconnect resembles the form of the ribbon bond interconnect in FR4. For the ribbon interconnect, the maximum input reflection is near −2 dB, and a spurious decrease in reflection toward −25 dB occurs at 78.5 GHz. The ribbon interconnect in LTCC has a high input reflection near −5 dB for the majority of the spectrum. Overall, the input return loss is not reduced by the transition to the LTCC substrate.

For the recessed placement, the variance of the input return is increased in the same manner that the variance of the insertion reflection was decreased. In this setting, the input reflection of the ribbon is near −5 dB while the input reflection of the printed interconnect is near −9 dB. The magnitude and stability of the input return loss for the printed interconnect in the recessed topology appear to provide a significant improvement when compared to the surface placements. The stripline interconnect appears to cause a dramatic reduction in the input return loss. A maximum input reflection near −10 dB is gathered for the frequency ranges. The input reflection drops below nearly −20 dB at 77.5 GHz.

Overall, the output return loss is greater than the input return loss for each of the assembly methods considered. In the FR4 interconnects, the ribbon and printed interconnect methods have high output reflections that do not decrease past −3 dB. However, there are many similarities between trends in the output return loss mimic those in the input return loss. As with the input reflection, the output reflection for the ribbon bond in the LTCC remains high near −3 dB. The output reflections for the LTCC printed interconnects also decrease near 78.5 GHz, similar to the input reflections. For the recessed placement, the improvements to the output return loss are similar to those for the input return loss. The ribbon-bonded method does not provide a clear reduction in the magnitude of the loss, but the printed method does. Additionally, the printed interconnect on recessed LTCC improves the linearity of the output return loss significantly.

The stripline interconnect causes a reduction in the output return loss that is similar to the reduction it causes in input return loss. Furthermore, the form of the output and input return losses are very similar, although the output return loss is increased by a decibel.

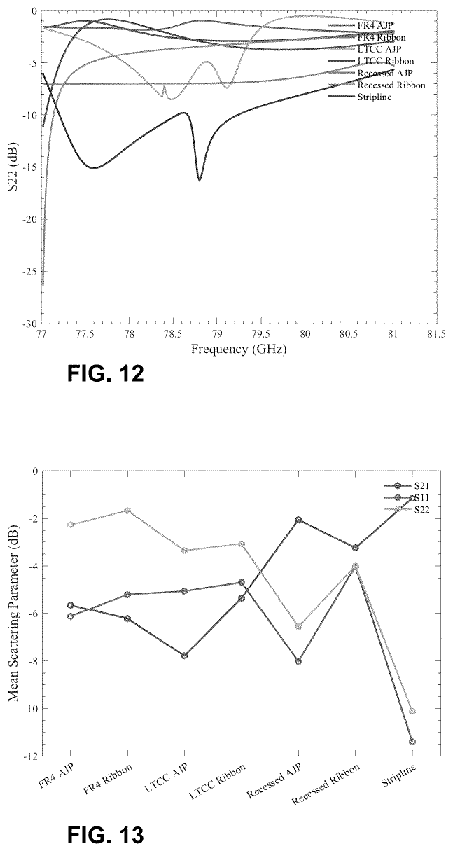

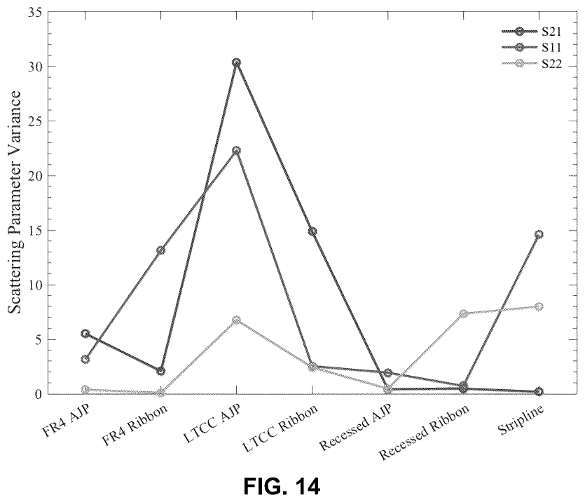

FIGS. 13 and 14 more clearly summarize the performance of each interconnect method by presenting the average and the variance, respectively, of the scattering parameters. For the surface placements, the mean insertion loss, input return loss, and output return loss are comparable. The LTCC interconnects provide a slight reduction in the input return loss and a slight increase in the output return loss. The variance of the insertion loss is higher for the LTCC surface placements, and for printed interconnect on the PCB surface. In the LTCC, the printed interconnect increases the return losses compared to the ribbon-bonded method. Apart from the differences in field distribution along the lines, the differences in the performance of the FR4 and LTCC substrates are most likely due to differences in the modal transitions required by each substrate. While the die is placed at an equal height above the GCPW in both scenarios, there is a greater change in the height of the transmission medium for FR4.

The improvements for the recessed method are clearly visible compared to the surface placement. The average insertion losses for the surface placement are between 2 dB and 3 dB for these interconnects. The recessed ribbon bond causes an increase in the input return loss and a decrease in the output return loss compared to the surface placements. However, the recessed AJP interconnect causes a significant reduction in both return losses when compared to the surface placements. Both recessed methods contribute to decreases in the variance for all losses, except for the output return loss for the recessed ribbon bond, which is slightly higher than that for the surface placements. Overall both recessed methods decrease insertion loss, and the printed interconnect reduces the return losses.

The stripline interconnect presents significant improvements. The insertion loss of the stripline interconnect represents an 80% reduction compared to the FR4 ribbon bond interconnect. Furthermore, the magnitude of the average input and output reflection coefficients are reduced by 100%, and 400%, respectively. The variance of the insertion loss is increased by the stripline method, but the variance of the return losses is increased.

The operation of the stripline MMIC interconnect on recessed LTCC is thoroughly demonstrated through three-dimensional electromagnetic simulation. A W-Band power amplifier is selected for the wafer in the demonstration, and a ground coplanar waveguide line is selected for the transmission line. Several alternative interconnect methods were simulated to demonstrate performance improvement. These included a ribbon-bonded interconnect, an aerosol jet-printed interconnect, and a recessed aerosol jet-printed interconnect. FR4 and LTCC substrates are used to compare the interconnects that are not recessed.

The W-band power amplifier MMIC was selected as a millimeter wave component whose integration is critical to system performance. For example, this component may be integrated into the transmit chain of W-Band radar to achieve a higher transmit power. The official operational frequency for each of the power amplifiers is 81-86 GHz. However, the amplifier displays sufficient gain and linearity down to 77 GHz. The power amplifier has a form factor of 2.999 mm×3.799 mm×0.05 mm. The RF Bond pads on the die are 90 um2 with 40 um between them. The input and output ports have an impedance of 50 ohms. GCPW transmission lines with 50-ohm impedance bring the W-Band signal to and from the die.

The electromagnetic simulation uses the dielectric constants and finite conductivities of the materials in the die assembly. Gold is used for the ribbon, and silver is used for the metalization. Rogers 4350 is used for the FR4 dielectric, and Dupont 9K7 is used for the LTCC tape system. The dielectric constants are 3.66 and 7.1, respectively. The loss tangents of the dielectrics are not included in the simulation, so the effect of the dielectric constant can be viewed in isolation. The LTCC has a dielectric loss tangent of less than a quarter of the FR4 dielectric. Therefore, any relative improvement for LTCC compared to FR4 is slightly better than depicted.

The thickness of the FR4 dielectric was 4 mils thick, and the LTCC dielectric was 5 mils thick. The spacing between the power amplifier die and the transmission line was 5.5 mil. Smaller distances may lead to better performance since a longer interconnect will experience more resistive losses, inductive losses, and parasitic effects. However, the fabrication complexity increases as the separation between the wafer and the transmission line decrease. A GCPW transmission line measuring 5.5 mm in length was included in the simulation. The scattering parameters are measured between 77 and 81 GHz. A lumped port was used at the input of the GCPW, and another was included at the pad of the power amplifier. The attenuation of the GCPW was near 0.07 dB/mm.

The arch of the ribbon interconnects was kept reasonably low to represent a practical bond profile. The center conductor of the aerosol-jet-printed interconnects was tapered so that the width of the center conductor on the GCPW gradually changed to the width of the pad on the power amplifier. Similarly, the width of the coplanar grounds of the aerosol-jet-printed interconnects are tapered so that the width of the center conductor on the GCPW gradually changes to the width of the pad on the power amplifier. The AJP interconnects are formed by first printing a dielectric ramp, then the metallization. In the surface placements, the dielectric ramps upward, while it ramps downward in the recessed placement.

The stripline interconnect is formed using additions to the recessed AJP interconnect. A dielectric is printed over the signal line and within the coplanar regions between the signal and the ground. The thickness of this dielectric is equivalent to the dielectric thickness in the GCPW, so the distance between the signal line and the shield is equal to the distance between the signal and the underlying ground plane. The shield is tapered in the same manner as the printed interconnect, forming a tapered stripline.

First, the performance of LTCC interconnects, and FR4 interconnects was compared and insertion losses near 6 dB were achieved. The input reflection coefficients are near −5 dB, while the output reflection coefficients are near −3 dB. While the LTCC reduces the output reflection, it increases the input reflection. Next, the superior electrical performance of the recessed topologies is demonstrated. The insertion loss is reduced near 3 dB for the ribbon bond and aerosol-jet-printed interconnects. The variance for the insertion loss of the recessed interconnects is below 1 dB.

In contrast, the variance of surface interconnects is greater than 2 dB. Lastly, the performance improvement for the AJP stripline interconnect is shown. The insertion loss is reduced to 1 dB, with less than 0.25 variance. The reflection coefficients are reduced to −12 dB.

Ultimately, the superior performance of the stripline MMIC interconnect on recessed LTCC has been demonstrated methodically. A high-performance W-Band amplifier was selected for the demonstration. First, the performance of ribbon bond and AJP interconnects are compared using FR4 and LTCC substrates. Next, recessed geometries that leverage the high thermal conductivity and 3D integration of LTCC are simulated. An AJP stripline interconnect is designed to shield unwanted signals, prevent radiative losses, and reduce dispersion. The performance of the FR4 and LTCC interconnects is comparable in the surface placement topology. While both recessed interconnects reduce the insertion losses compared to the surface placement, recessed AJP reduces the input losses in addition to the insertion losses. The stripline interconnect significantly reduces the insertion loss, the reflection losses, and the variance of the insertion loss compared to standard interconnect methods.

This description herein presents the design of an aerosol jet-printed stripline interconnect on a recessed LTCC substrate. A W-Band power amplifier MMIC is used to demonstrate the interconnect. The fabrication method for the recessed LTCC substrate and the stripline interconnect is described. The stripline reduces the insertion loss and variation in a loss significantly when compared to other methods. The stripline method developed here contains an 83% reduction in insertion loss and a 400% decrease in the output reflection coefficient compared to the FR4 ribbon bond method. The stripline assembly method is being fabricated to verify the simulation results.

The improvement for the stripline interconnect is illustrated through comparison with several other assembly methodologies. The performance for LTCC interconnects is compared against FR4, and the improvement for recessed geometries compared to surface placements is simulated. Overall, the minimum loss is reduced, but the maximum loss is increased for the ribbon and printed interconnects when transitioning from the FR4 to the LTCC substrate. The recessed placements reduce the magnitude and variance of the insertion loss. Within each setting, the performance of the ribbon bond and FR4 methods remain similar, except for the recessed placement in which the printed interconnect excels. This illustrates the methodical development of high-performance, high-frequency MMIC assembly with considerations for thermal and electrical performance.

Although this study does not quantify the amount, the shielding of the stripline interconnect method should contribute to improvements in signal integrity for systems such as millimeter wave radar. These include the reduction of parasitic coupling and interference, and the reduction of signal dispersion, or ultimately, phase noise. Interferences studies and wave propagation studies remain future areas of research.

It is evident that modifications and variations can be made to what has been described and illustrated herein without departing from the scope of this disclosure. Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

Indeed, the stripline MMIC interconnect is a versatile and promising technology

that can be applied to almost any wafer assembly method, and further developments are within the scope of this disclosure. For example, the onset and tapered profile of the stripline interconnect may be further optimized to improve the insertion and return losses, isolation, and dispersion of the interconnect. Exponential tapering methods, which have been shown to provide better impedance-matching performance than linear methods for basic transmission lines, may be used to optimize the tapered profile.

What is claimed is:

1. A stripline interconnect system, comprising:
a substrate having a recessed area formed therein;
an integrated circuit wafer positioned within the recessed area; and
a stripline interconnect extending over the recessed wafer and on the substrate, the stripilne interconnect comprising a metal shield over a printed metal interconnect and facilitating transfer of high-frequency signals between the integrated circuit wafer in the recessed area and external circuitry.

2. The stripline interconnect system of claim 1, wherein the stripline is embedded between two parallel ground planes on the substrate, thereby ensuring confinement of electromagnetic waves within the system.

3. The stripline interconnect system of claim 1, wherein the metal shield is tapered to augment impedance-matching performance.

4. The stripline interconnect system of claim 1, wherein the integrated circuit wafer has its top surface positioned beneath the height of the transmission structure.

5. A method of producing a stripline interconnect, comprising:
disposing an integrated circuit wafer within a recessed area formed in a substrate;
additively manufacturing a dielectric ramp on the substrate;
using aerosol jet printing to create a center conductor running from the substrate, on the dielectric ramp, to wafer pads on the integrated circuit wafer;
printing a dielectric over the center conductor and its sides, yielding an arch shape on the substrate; and
printing a metal shield on the dielectric, thereby forming the stripline interconnect.

6. The method of claim 5, wherein the dielectric ramp is manufactured to transition in height from the transmission dielectric to that of the wafer on the substrate.

7. The method of claim 5, wherein the printed metal interconnect tapers in width from the transmission line's width to the wafer pad's width on the substrate.

8. The method of claim 5, wherein the printed dielectric maintains a consistent distance between the stripline and shield and between signal and ground plane beneath on the substrate.
